(19) United States
(12) Patent Application Publication
(10) Pub. No.: US 2006/0226420 A1
(43) Pub. Date: Oct. 12, 2006

(54) Organic thin-film transistor and process for fabricating the same, active matrix type display employing it and radio identification tag

(75) Inventors: Norishige Nanai, Hirakata-shi (JP); Shinichi Yamamoto, Hirakata-shi (JP); Tetsuo Kawakita, Kyotanabe-shi (JP)

Correspondence Address: HAMRE, SCHUMANN, MUELLER & LARSON P.C., P.O. BOX 2902-0902, MINNEAPOLIS, MN, 55402, US

(73) Assignee: Matsushita Electric Industrial Co., Ltd., Kadoma, Osaka (JP)

(21) Appl. No.: 10/562,739

(22) PCT Filed: Jul. 8, 2004
(86) PCT No.: PCT/JP04/10066

§ 371 Date: Jun. 5, 2006

(30) Foreign Application Priority Data
Jul. 10, 2003 (JP) 2003-272851

(51) Int. Cl. H01L 29/08

(52) U.S. Cl. 257/40

(57) ABSTRACT

An organic thin film transistor of the present invention includes a substrate (11) and a semiconductor layer (14) made of an organic semiconductor and formed on the substrate (11). The semiconductor layer (14) is composed of crystals of the organic semiconductor, and a crystal phase of the crystals is the same as a crystal phase of energetically most stable bulk crystals of the organic semiconductor. A method for manufacturing the organic thin film transistor of the present invention includes forming the semiconductor layer (14) by depositing an organic semiconductor on the substrate (11). The organic semiconductor is deposited at a deposition rate of 0.1 to 1 nm/min while maintaining the temperature of the substrate (11) in the range of 40 to 150° C.

### TECHNICAL FIELD

The present invention relates to an organic thin film transistor including a semiconductor layer made of an organic semiconductor and a method for manufacturing the organic thin film transistor, and an active matrix display and a radio recognition tag that use the organic thin film transistor.

### BACKGROUND ART

At present, a thin film transistor (referred to as “TFT” in the following) is used as a driving device for an active matrix liquid crystal display or the like. In a general TFT configuration, a source electrode and a drain electrode are formed in contact with a semiconductor layer, and a gate electrode is located on the other side of the semiconductor layer via an insulating layer. This configuration allows a current flowing between the source electrode and the gate electrode to be controlled by an electric field that is applied from the gate electrode.

The semiconductor layer of a commercially available TFT is made of amorphous silicon or low-temperature polysilicon, which are inexpensive, though inferior to crystalline silicon in property. The insulating layer of a commercially available TFT is made of silicon oxide or silicon nitride. The manufacturing process of the TFT using these materials is a high-cost process because it requires a large-scale apparatus, e.g., for plasma chemical vapor deposition (plasma CVD) or a thin film control apparatus for precision machining. Moreover, the manufacturing process generally involves a process at temperatures higher than 350° C. Thus, there is a limit to the materials that can be used.

On the other hand, an organic semiconductor recently has attracted attention as a semiconductor material of the TFT, and TFTs with various configurations using this organic semiconductor (referred to as “organic TFT” in the following) have been proposed. Compared to the above inorganic semiconductor, the organic semiconductor may be formed by a low-cost process such as spin coating, ink jet printing or dip coating, and the formation by a low-temperature process also can be expected. Using the low-cost process and the low-temperature process makes it possible to form the TFT on a flexible substrate or a large area substrate. Thus, the TFT has a chance of increasing the range of application to, e.g., a sheet-like or paper-like display or a large-screen display. Since the organic TFT can reduce both thickness and weight, there is also a good chance that it will be applied to a radio recognition tag such as a radio frequency identification (RFID) tag.

As the organic semiconductor, an organic TFT using pentacene that can improve the carrier mobility with a lower operating voltage has been reported (e.g., JP 2000-269515 A (referred to as patent document 1 in the following) or C. D. Dimitrakopoulos et al., “Organic Thin Film Transistors: A Review of Recent Advances”, IBM J. RES. & DEV., Vol. 45, No. 1, January 2001, p 19, FIG. 7 (referred to as non-patent document 1 in the following)).

FIG. 7 is a cross-sectional view showing the configuration of a conventional organic TFT. As shown in FIG. 7, the organic TFT 100 includes a substrate 101, a gate electrode 102 formed on the substrate 101, a gate insulating layer 103 and a semiconductor layer 104 that are formed in this order on the substrate 101 and the gate electrode 102, and a source electrode 105 and a drain electrode 106 that are formed separately on the semiconductor layer 104. The gate electrode 102 is located opposite to a field-effect channel 104a of the semiconductor layer 104.

In a method for manufacturing the organic TFT 100, first, a metal electrode is formed as the gate electrode 102 on the substrate 101 by, e.g., vapor deposition. Then, an inorganic oxide layer is formed as the gate insulating layer 103 on the gate electrode 102 by, e.g., sputtering. Subsequently, an organic semiconductor layer is formed as the semiconductor layer 104 on the gate insulating layer 103 by, e.g., vapor deposition. Finally, metal electrodes are formed as the source electrode 105 and the drain electrode 106 on the semiconductor layer 104 by, e.g., vapor deposition. Thus, the organic TFT 100 is produced.

In the organic TFT 100 proposed by the non-patent document 1, the semiconductor layer 104 is formed by depositing pentacene on the gate insulating layer 103 at a deposition rate of 6 nm/min while maintaining the temperature of the substrate 101 at room temperature (27° C.). This organic TFT 100 can achieve a high value of carrier mobility in the field-effect channel 104a, i.e., 0.6 cm²/Vs.

However, the pentacene crystals constituting the semiconductor layer 104 of the organic TFT 100 have a thermally unstable crystal structure. Therefore, if the organic TFT 100 is allowed to stand for a long time at high temperatures, the crystal structure may be changed to degrade the carrier mobility over time.

FIG. 8 is a conceptual diagram for explaining a phenomenon in which the crystal structure of the pentacene crystals constituting the semiconductor layer 104 of the organic TFT 100 is changed by heat. FIG. 8A shows the state before heating. FIG. 8B shows the state after heating at 60° C. for 100 hours. The crystal structure (FIG. 8A) of pentacene P has a single crystal phase 110 before heating. However, the X-ray diffraction analysis conducted by the present inventors confirmed that part of the crystal structure is changed to a more stable crystal phase 111 (FIG. 8B) after heating. Consequently, the carrier mobility was reduced from 0.6 cm²/Vs to 0.001 cm²/Vs or less due to many grain boundaries 113 generated between the crystal phase 110 and the crystal phase 111.

The patent document 1 proposes an organic TFT and a method for manufacturing the organic TFT based on the same technical findings as the non-patent document 1. In the organic TFT of the patent document 1, however, the crystal structure of the organic semiconductor constituting the semiconductor layer also is thermally unstable. Therefore, like the non-patent document 1, the carrier mobility may be degraded over time.

### DISCLOSURE OF INVENTION

Therefore, with the foregoing in mind, it is an object of the present invention to provide an organic TFT that can suppress the degradation of carrier mobility over time and a method for manufacturing the organic TFT, and an active matrix display and a radio recognition tag that use the organic TFT.

An organic TFT of the present invention includes a substrate and a semiconductor layer made of an organic semiconductor and formed on the substrate. The semiconductor layer is composed of crystals of the organic semiconductor, and a crystal phase of the crystals is the same as a crystal phase of energetically most stable bulk crystals of the organic semiconductor.

In this application, the “energetically most stable bulk crystals of the organic semiconductor” may be defined as follows. The organic semiconductor is vaporized and cooled slowly at a predetermined precipitation temperature to precipitate bulk crystals, and the bulk crystals thus obtained do not substantially change in crystal phase between 27° C. and 180° C. Specifically, in the X-ray diffraction patterns of the crystals, the peak intensity of a diffraction line at 27° C. is used as a reference. When the diffraction line intensity at the same peak position is maintained within the range of 90 to 110% between 27° C. and 180° C., the crystals are identified as energetically most stable bulk crystals. However, when the crystals are changed to a liquid or gas while varying the temperature from 27° C. to 180° C., the crystals can be identified as energetically most stable bulk crystals if the diffraction line intensity at the same peak position is maintained within the range of 90 to 110% between 27° C. and a temperature that is 20° C. lower than the temperature at which the crystals are changed to a liquid or gas.

Moreover, the crystal phase is defined to be “the same as a crystal phase of energetically most stable bulk crystals of the organic semiconductor”. This means that the same crystal phase as that of the energetically most stable bulk crystals makes up 90% or more of the crystals of the organic semiconductor.

A method for manufacturing an organic TFT of the present invention includes forming a semiconductor layer by depositing an organic semiconductor on a substrate. The organic semiconductor is deposited at a deposition rate of 0.1 to 1 nm/min while maintaining the temperature of the substrate in the range of 40 to 150° C.

An active matrix display of the present invention includes a plurality of the organic TFTs of the present invention as switching elements for pixels.

A radio recognition tag of the present invention includes an integrated circuit portion. The integrated circuit portion includes the organic TFT of the present invention.

### BRIEF DESCRIPTION OF DRAWINGS

FIG. 1 is a cross-sectional view showing the configuration of an organic TFT of Embodiment 1 of the present invention.

FIG. 2 is a flow chart showing a method for manufacturing an organic TFT of Embodiment 1 of the present invention.

FIG. 3 is a cross-sectional view showing the configuration of an organic TFT of Embodiment 2 of the present invention.

FIG. 4 is a partially cutaway perspective view of an active matrix display of Embodiment 3 of the present invention.

FIG. 5 is a perspective view of a radio recognition tag of Embodiment 4 of the present invention.

FIG. 6 shows X-ray diffraction patterns of pentacene crystals. FIG. 6A shows the X-ray diffraction patterns of energetically most stable bulk crystals of pentacene. FIG. 6B shows the X-ray diffraction patterns of pentacene crystals constituting a semiconductor layer of Example 1 of the present invention. FIG. 6C shows the X-ray diffraction patterns of pentacene crystals constituting a semiconductor layer of Comparative Example 1. FIG. 6D shows the X-ray diffraction patterns of pentacene crystals constituting a semiconductor layer of Comparative Example 2.

FIG. 7 is a cross-sectional view showing the configuration of a conventional organic TFT.

FIG. 8 is a conceptual diagram for explaining a phenomenon in which a crystal structure of an organic semiconductor constituting a semiconductor layer of a conventional organic TFT is changed by heat. FIG. 8A shows the state before heating. FIG. 8B shows the state after heating at 60° for 100 hours.

### DESCRIPTION OF THE INVENTION

An organic TFT of the present invention includes a substrate and a semiconductor layer made of an organic semiconductor and formed on the substrate. The substrate is not particularly limited and is preferably a plastic plate that can be reduced in both thickness and weight, or a plastic film that can improve mechanical flexibility and impact resistance. The preferred materials for the plastic plate and the plastic film may be, e.g., polyimide, aromatic polyester such as polyethylene naphthalate, polyacetal, polyurea, polyphenyl sulfone, or polycarbonate. The thickness of the substrate is preferably 0.02 to 2 mm.

As the organic semiconductor, e.g., a low molecular weight organic semiconductor material such as π-conjugated oligomer or a high molecular weight organic semiconductor material such as π-conjugated polymer can be used. In particular, the organic semiconductor preferably includes at least one material selected from an acene-based material, a phthalocyanine-based material, and a thiophene-based material. The acene-based material is preferably pentacene. The phthalocyanine-based material is preferably a phthalocyanine complex in which a metal is arranged at the center. In view of the electric characteristics and storage stability, the preferred central metal may be, e.g., a single metal such as copper, iron, nickel, cobalt or zinc, or a composite metal containing titanium or vanadium. The thiophene-based material may include oligothiophene and polythiophene. In view of the crystallinity and storage stability, a material in which a functional group such as an alkyl group is introduced into the side chains or the end of a chain also can be used. Moreover, a copolymer of a thiophene monomer and other monomers can be used. Specific examples of the copolymer include poly(fluorene-co-bithiophene), poly(3-alkylthiophene), and poly(ethylenedioxythiophene). The thickness of the semiconductor layer made of the organic semiconductor is preferably 0.03 to 1 μm. Particularly for the organic TFT having a top gate structure, the thickness of the semiconductor layer is preferably 0.03 to 0.3 μm.

In the organic TFT of the present invention, the semiconductor layer is composed of crystals of the organic semiconductor, and a crystal phase of the crystals is the same as a crystal phase of the energetically most stable bulk crystals of the organic semiconductor. This can prevent a change in crystal phase of the crystals constituting the semiconductor layer and suppress the degradation of carrier mobility over time. As a result, the organic TFT can have a longer life. The crystal phase may be confirmed, e.g., by analytical methods such as X-ray diffraction and absorptiometric analysis.

In the organic TFT of the present invention, it is preferable that the peak position of a diffraction line that indicates the maximum peak intensity value in X-ray diffraction patterns of the crystals constituting the semiconductor layer coincides with the peak position of any one of diffraction lines in X-ray diffraction patterns of the energetically most stable bulk crystals of the organic semiconductor. This can clarify that the crystals constituting the semiconductor layer and the bulk crystals are identical in crystal phase, and thus reliably can suppress the degradation of carrier mobility over time. It is more preferable that the total intensity value of diffraction lines derived from a crystal phase having the maximum peak intensity value is 90 to 100% of the total intensity value of all diffraction lines in the X-ray diffraction patterns of the crystals constituting the semiconductor layer. This can further clarify that the crystals constituting the semiconductor layer and the bulk crystals are identical in crystal phase, and thus can suppress the degradation of carrier mobility more reliably over time.

In the organic TFT of the present invention, pentacene may be used as the organic semiconductor, and the peak of the diffraction line that indicates the maximum peak intensity value in the X-ray diffraction patterns of the crystals constituting the semiconductor layer may be positioned at d=1.43 nm, where d represents a distance between the Bragg planes of the crystals. This can improve the effect of suppressing the degradation of carrier mobility over time. In the organic TFT of the present invention, copper phthalocyanine may be used as the organic semiconductor, and the peak of the diffraction line that indicates the maximum peak intensity value in the X-ray diffraction patterns of the crystals constituting the semiconductor layer may be positioned at d=1.25 nm. This also can improve the effect of suppressing the degradation of carrier mobility over time. In the organic TFT of the present invention, sexithiophene may be used as the organic semiconductor, and the peak of the diffraction line that indicates the maximum peak intensity value in the X-ray diffraction patterns of the crystals constituting the semiconductor layer may be positioned at d=2.24 nm. This also can improve the effect of suppressing the degradation of carrier mobility over time.

It is preferable that the organic TFT of the present invention further includes electrodes for transferring charge to the semiconductor layer, and the electrodes are made of at least one selected from a metal and a conductive polymer. When at least one of the metal and the conductive polymer is used as an electrode material, the charge transfer between the semiconductor layer and the electrodes can be performed more smoothly. The electrodes may be, e.g., a source electrode and a drain electrode that are in contact with the semiconductor layer and formed separately. The preferred metal material for the electrodes may be, e.g., gold, copper, nickel, aluminum, titanium, or molybdenum. The preferred conductive polymer material for the electrodes may be, e.g., polypyrrole, polythiophene, polyaniline, or polyphenylene vinylene. The thickness of the electrodes is preferably 0.03 to 0.3 μm.

A method for manufacturing an organic TFT of the present invention includes forming a semiconductor layer by depositing an organic semiconductor on a substrate. The organic semiconductor is deposited at a deposition rate of 0.1 to 1 nm/min, preferably 0.1 to 0.5 nm/min while maintaining the temperature of the substrate in the range of 40 to 150° C., preferably in the range of 50 to 90° C. This manufacturing method easily can produce an organic TFT in which the crystals of the organic semiconductor constituting the semiconductor layer have the same crystal phase as the energetically most stable bulk crystals of the organic semiconductor. The materials of the substrate and the organic semiconductor may be the same as those of the above organic TFT of the present invention.

The manufacturing method of the organic TFT of the present invention further may include cooling the semiconductor layer slowly after the semiconductor layer is formed by depositing the organic semiconductor. This can stabilize the crystals of the organic semiconductor constituting the semiconductor layer and efficiently suppress a change in crystal phase of the crystals. In the manufacturing method, it is preferable that the semiconductor layer is cooled slowly by decreasing the ambient temperature around the semiconductor layer at a rate of 1° C./min or less, more preferably 0.2° C./min or less. This can stabilize the crystals more easily.

The manufacturing method of the organic TFT of the present invention further may include heat-treating the semiconductor layer while maintaining the temperature of the substrate in the range of 50 to 150° C. after the semiconductor layer is formed by depositing the organic semiconductor. This also can stabilize the crystals of the organic semiconductor constituting the semiconductor layer.

The manufacturing method of the organic TFT of the present invention further may include forming an electrode by depositing an electrode material on the semiconductor layer while maintaining the temperature of the substrate at 45° C. or less after the semiconductor layer is formed by depositing the organic semiconductor. This can suppress damage to the organic semiconductor during the deposition of the electrode material and provide the organic TFT with more stable characteristics. The electrode material may be the same as that of the above organic TFT of the present invention.

An active matrix display of the present invention includes a plurality of the organic TFTs of the present invention as switching elements for pixels. A radio recognition tag of the present invention includes an integrated circuit portion. The integrated circuit portion includes the organic TFT of the present invention. Both the active matrix display and the radio recognition tag include the above organic TFT of the present invention. Therefore, the life of the organic TFT can be increased, which in turn increases the life of the products themselves. The active matrix display of the present invention may be, e.g., a liquid crystal display system, an electrophoretic image display system, an organic EL system, an electrochromic display (ECD) system, an electrolytic deposition system, a display system using an electronic particulate material, or an interferometric modulation micro electro mechanical system. The radio recognition tag of the present invention may be, e.g., a radio frequency identification (RFID) tag.

Hereinafter, embodiments of the present invention will be described with reference to the drawings.

### Embodiment 1

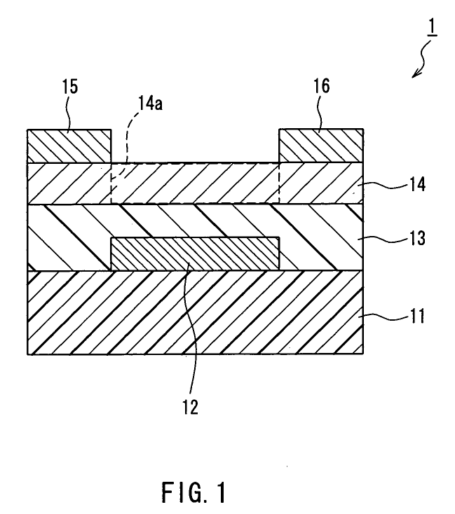

An organic TFT of Embodiment 1 of the present invention will be described below. FIG. 1 is a cross-sectional view showing the configuration of the organic TFT of Embodiment 1.

As shown in FIG. 1, the organic TFT 1 includes a substrate 11, a gate electrode 12 formed on the substrate 11, a gate insulating layer 13 and a semiconductor layer 14 made of an organic semiconductor that are formed in this order on the substrate 11 and the gate electrode 12, and a source electrode 15 and a drain electrode 16 that are formed separately on the semiconductor layer 14. The gate electrode 12 is located opposite to a field-effect channel 14a of the semiconductor layer 14. The semiconductor layer 14 is composed of crystals of the organic semiconductor, and a crystal phase of the crystals is the same as a crystal phase of energetically most stable bulk crystals of the organic semiconductor. This can prevent a change in crystal phase of the crystals constituting the semiconductor layer 14 and suppress the degradation of carrier mobility in the field-effect channel 14a over time.

A conductive material can be used for the gate electrode 12, the source electrode 15, and the drain electrode 16. The conductive material is not particularly limited, as long as it does not react with the substrate material or the organic semiconductor material. Examples of the conductive material include a noble metal such as gold, platinum or palladium, an alkali or alkaline-earth metal such as lithium, cesium, calcium or magnesium, a metal such as copper, nickel, aluminum, titanium or molybdenum, and an alloy of these metals. Moreover, a conductive polymer such as polypyrrole, polythiophene, polyaniline or polyphenylene vinylene, or silicon doped with specific purities also can be used. In particular, the gate electrode 12 can be operated with a material having a larger electric resistance than the other electrodes. Therefore, the material of the gate electrode 12 may differ from that of the source and drain electrodes 15, 16, e.g., to facilitate the fabrication.

The material of the gate insulating layer 13 may be, e.g., an inorganic oxide such as barium zirconate titanate (BZT). The BZT has a large dielectric constant and thus can improve the carrier mobility. The gate insulating layer 13 including the inorganic oxide can be formed, e.g., by sputtering at low temperature, a spinning process, vapor deposition, or laser ablation. These methods are preferred particularly when a plastic plate or plastic film is used as the substrate, since the gate insulating layer 13 can be formed in a low-temperature process at 250° or less.

The material of the gate insulating layer 13 may be an organic insulating material such as a polymeric material. In this case, a low-temperature process, e.g., spin coating, ink jet printing, or electrodeposition is suitable as a method for forming the gate insulating layer 13.

Any other materials can be used instead of the above materials for the gate insulating layer 13, as long as they are electrical insulating materials that do not react with the substrate material, the electrode material, and the organic semiconductor material. It is also possible to use a substance with a higher dielectric constant as a material for the gate insulating layer 13 in order to reduce the gate voltage of the organic TFT 1. For example, a ferroelectric compound may be used, as disclosed in U.S. Pat. No. 5,981,970. In addition to the inorganic materials, organic materials having a large dielectric constant such as polyvinylidene fluoride or polyvinylidene cyanide may be used.

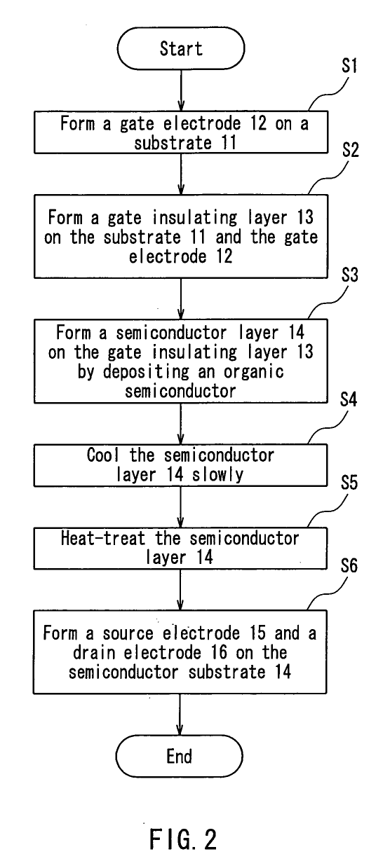

Next, an example of a method for manufacturing the organic TFT 1 of Embodiment 1 of the present invention will be described by referring to FIGS. 1 and 2. FIG. 2 is a flow chart showing the manufacturing method of the organic TFT 1 of Embodiment 1.

As shown in FIG. 2, first, the gate electrode 12 (FIG. 1) is formed, e.g., by depositing a metal such as gold on the substrate 11 (FIG. 1) using a mask (step S1). Then, the gate insulating layer 13 (FIG. 1) is formed, e.g., by depositing an inorganic oxide such as BZT on the substrate 11 and the gate electrode 12 by sputtering or the like (step S2). Subsequently, the semiconductor layer 14 (FIG. 1) is formed by depositing an organic semiconductor such as pentacene on the gate insulating layer 13 at a deposition rate of 0.1 to 1 nm/min while maintaining the temperature of the substrate 11 in the range of 40 to 150° C. (step S3). The semiconductor layer 14 is cooled slowly by decreasing the ambient temperature around the semiconductor layer 14 at a rate of 1° C./min or less (step S4). This process stabilizes the crystals of the organic semiconductor constituting the semiconductor layer 14. Then, the semiconductor layer 14 is heat-treated while maintaining the temperature of the substrate 11 in the range of 50 to 150° C. (step S5). This process further stabilizes the crystals of the organic semiconductor. Finally, the source electrode 15 and the drain electrode 16 (FIG. 1) are formed, e.g., by depositing a metal such as gold on the semiconductor layer 14 using a mask (step S6). Thus, the organic TFT 1 is produced. When the electrode materials of the source electrode 15 and the drain electrode 16 are deposited while maintaining the temperature of the substrate 11 at 45° C. or less, the organic semiconductor is not susceptible to damage during the deposition of the electrode materials, so that the organic TFT 1 can have more stable characteristics.

The above explanation is an example of the manufacturing method of the organic TFT 1 in Embodiment 1 of the present invention. However, the present invention is not limited thereto, and the steps S4 and S5 may be removed from the manufacturing method.

### Embodiment 2

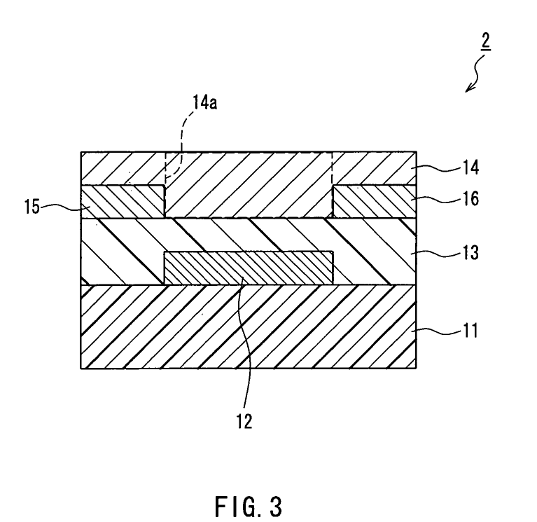

An organic TFT of Embodiment 2 of the present invention will be described below. FIG. 3 is a cross-sectional view showing the configuration of the organic TFT of Embodiment 2. The same components as those of the organic TFT (FIG. 1) in Embodiment 1 are denoted by the same reference numerals, and the explanation will not be repeated.

As shown in FIG. 3, the organic TFT 2 includes a substrate 11, a gate electrode 12 formed on the substrate 11, a gate insulating layer 13 formed on the substrate 11 and the gate electrode 12, a source electrode 15 and a drain electrode 16 that are formed separately on the gate insulating layer 13, and a semiconductor layer 14 made of an organic semiconductor that is formed on the gate insulating layer 13, the source electrode 15, and the drain electrode 16. The gate electrode 12 is located opposite to a field-effect channel 14a of the semiconductor layer 14. The semiconductor layer 14 is composed of crystals of the organic semiconductor, and a crystal phase of the crystals is the same as a crystal phase of energetically most stable bulk crystals of the organic semiconductor. This can prevent a change in crystal phase of the crystals constituting the semiconductor layer 14 and suppress the degradation of carrier mobility in the field-effect channel 14a over time. The organic TFT 2 of Embodiment 2 differs from the organic TFT 1 of Embodiment 1 only in the arrangement of the layers and can be manufactured in the same manner as the organic TFT 1. Therefore, the explanation of a method for manufacturing the organic TFT 2 will not be repeated.

### Embodiment 3

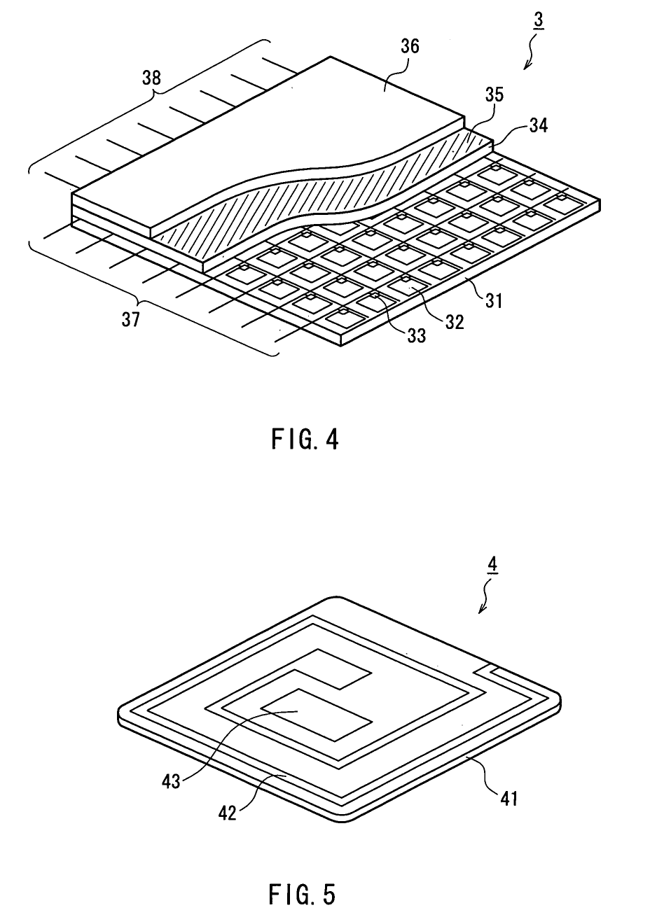

Embodiment 3 of the present invention will be described by referring to the drawings. FIG. 4 is a partially cutaway perspective view of an active matrix display (organic EL display) of Embodiment 3.

As shown in FIG. 4, the active matrix display (simply referred to as “display” in the following) 3 includes a plastic substrate 31, a plurality of pixel electrodes 32 arranged in a matrix on the plastic substrate 31, a plurality of organic TFT driving circuits 33 connected to the pixel electrodes 32 and arranged in an array on the plastic substrate 31, an organic EL layer 34, a transparent electrode 35 and a protective film 36 that are formed in this order on the pixel electrodes 32 and the organic TFT driving circuits 33, and source electrode lines 37 and gate electrode lines 38 for connecting each of the organic TFT driving circuits 33 and a control circuit (not shown). In this case, the organic EL layer 34 is formed by stacking an electron transport layer, a light-emitting layer, a hole transport layer, and the like. The display 3 also includes the organic TFT according to either Embodiment 1 or 2 as a switching element for the pixel in each of the organic TFT driving circuits 33. Thus, the display 3 uses as the switching elements for the pixels the organic TFTs of the present invention that can suppress the degradation of carrier mobility over time. Therefore, the life of the organic TFT can be increased, which in turn increases the life of the display itself.

The above display has been described as an embodiment of the present invention, but the present invention is not limited thereto. For example, although the organic EL is used in the display of this embodiment, other display devices such as a liquid crystal display device may be used instead.

### Embodiment 4

Embodiment 4 of the present invention will be described by referring to the drawings. FIG. 5 is a perspective view of a radio recognition tag of Embodiment 4.

As shown in FIG. 5, the radio recognition tag 4 includes a film-shaped plastic substrate 41, and an antenna portion 42 and an integrated circuit portion 43 that are formed on the plastic substrate 41. The integrated circuit portion 43 includes the organic TFT according to either Embodiment 1 or 2. Thus, the radio recognition tag 4 uses in the integrated circuit portion 43 the organic TFT of the present invention that can suppress the degradation of carrier mobility over time. Therefore, the life of the organic TFT can be increased, which in turn increases the life of the radio recognition tag itself. The radio recognition tag 4 further may include a protective film on the surface.

The above radio recognition tag has been described as an embodiment of the present invention, but the present invention is not limited thereto. For example, the arrangement or configuration of the antenna portion and the integrated circuit portion may be determined as desired. Moreover, it is also possible to incorporate a logic circuit portion.

Examples of the present invention will be described below. However, the present invention is not limited to the following examples.

### EXAMPLE 1

Example 1 will be described by referring to FIG. 1 as an example of Embodiment 1 of the present invention. This example used the following materials: polyimide with a thickness of 0.25 mm as the substrate 11; polyimide as an organic insulating material of the gate insulating layer 13; pentacene (manufactured by Aldrich Chemical Co., Inc.) as an organic semiconductor material of the semiconductor layer 14; and gold as a conductive material of the gate electrode 12, the source electrode 15, and the drain electrode 16.

In the manufacturing method of Example 1, first, the gate electrode 12 (thickness: 50 nm) was formed by depositing gold on the substrate 11 using a mask. Then, a polyimide precursor (CT4112 manufactured by Kyocera Chemical Corporation) was applied on the substrate 11 and the gate electrode 12 by spin coating. This was dried at 60° C. for 15 minutes, heated at 180° C. for 1 hour, and thus cured to form the gate insulating layer 13. The thickness of the gate insulating layer 13 was 0.75 μm. Subsequently, the semiconductor layer 14 (thickness: 70 nm) was formed by depositing pentacene on the gate insulating layer 13 at a deposition rate of 0.1 nm/min while maintaining the temperature of the substrate 11 at 70° C. Finally, the source electrode 15 (thickness: 50 nm) and the drain electrode 16 (thickness: 50 nm) were formed by depositing gold on the semiconductor layer 14 using a mask. Thus, the organic TFT 1 of Example 1 was produced. The distance (channel length) between the source electrode 15 and the drain electrode 16 was 100 μm. The width (channel width) of a region where the source electrode 15 and the drain electrode 16 face each other was 2 mm.

### COMPARATIVE EXAMPLES 1 AND 2

As comparative examples, an organic TFT of Comparative Example 1 and an organic TFT of Comparative Example 2 were produced in the same manner as Example 1 except that the semiconductor layer was formed by depositing pentacene on the gate insulating layer at a deposition rate of 6 nm/min while maintaining the temperature of the substrate at 27° C. (Comparative Example 1) and at 50° C. (Comparative Example 2).

Confirmation of Crystal Phase by X-Ray Diffraction Method

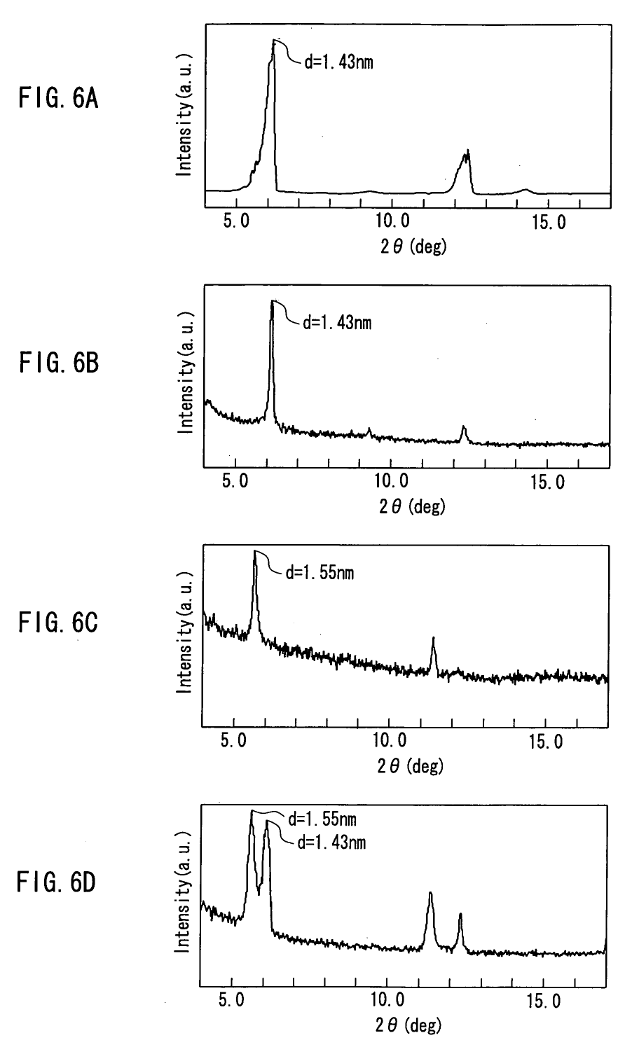

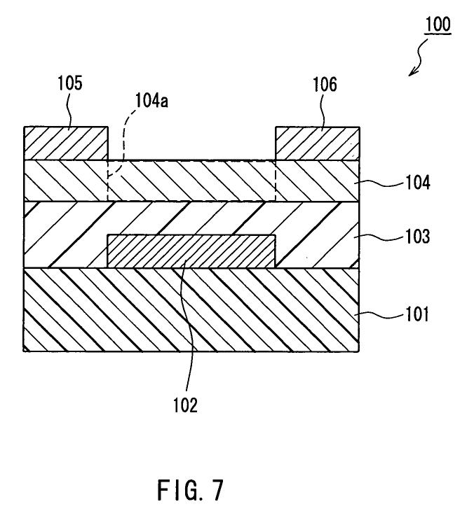

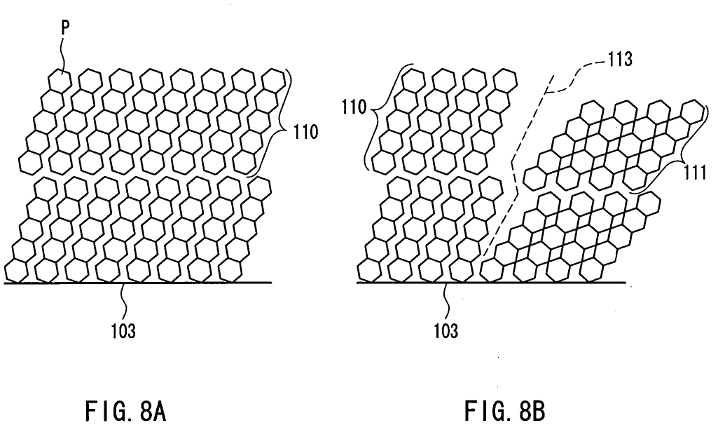

X-ray diffraction patterns of the pentacene crystals constituting the semiconductor layer were measured in Example 1, Comparative Example 1, and Comparative Example 2. The measurement of the X-ray diffraction patterns was performed by using RIGAKU RU 200 (RU 200 manufactured by Rigaku Corporation) with CuKα rays (wavelength λ=0.15418 nm). As a reference example, the energetically most stable bulk crystals of pentacene were produced, and the X-ray diffraction patterns were measured. FIG. 6 shows the results. FIG. 6A shows the X-ray diffraction patterns of the bulk crystals. FIG. 6B shows the X-ray diffraction patterns of the pentacene crystals constituting the semiconductor layer of Example 1. FIG. 6C shows the X-ray diffraction patterns of the pentacene crystals constituting the semiconductor layer of Comparative Example 1. FIG. 6D shows the X-ray diffraction patterns of the pentacene crystals constituting the semiconductor layer of Comparative Example 2. In each case, the data were measured at 27° C.

The bulk crystals of pentacene were produced by the following method.

Method for Producing the Bulk Crystals of Pentacene

Pentacene powder was put in a silica glass tube. Then, one end of the silica glass tube at which the pentacene powder was placed was heated at 200° C. and the other end was heated at 60° C. while reducing the pressure with a vacuum pump, so that a temperature gradient was created along the wall of the silica glass tube for precipitation. The pentacene crystals were sublimated and precipitated in a thickness of 0.1 mm or more on the wall of the silica glass tube. The reason the precipitated pentacene crystals had a thickness of at least 0.1 mm was that the pentacene crystals were not likely to be affected by the surface of the silica glass tube or the like, and it was relatively easy to produce energetically most stable crystals. Subsequently, the pentacene crystals were cooled slowly at 0.15° C./min. The pressure inside the silica glass tube was 1.3×10⁻² Pa.

The crystal phase of the bulk crystals of pentacene was confirmed by following method.

Method for Confirming the Crystal Phase of the Bulk Crystals of Pentacene

The resultant pentacene bulk crystal powder was put in a temperature variable X-ray sample holder, and X-ray diffraction patterns of the powder were measured at 27° C. and 180° C. by a θ-2θ method. Among the X-ray diffraction patterns thus obtained, the diffraction line at a position of d=1.43 nm corresponded to the diffraction line that appeared strongly on the X-ray diffraction patterns of the semiconductor layer of the organic TFT manufactured in Example 1. For the bulk crystals, there was another diffraction line, e.g., at a position of d=0.44 nm that was stronger in intensity than the diffraction line at a position of d=1.43 nm. For the semiconductor layer of the organic TFT, however, since the crystals were oriented in a specific direction with respect to the substrate, the diffraction lines, except for the limited orientation, were not observed. Therefore, the crystal phase was confirmed by comparing the d values in the specific orientation (d=1.43 nm in Example 1). The measurement was performed in an atmosphere of nitrogen at atmospheric pressure (1.0×10⁵ Pa).

In the X-ray diffraction patterns of the bulk crystals, the diffraction line intensity at 27° C. for d=1.43 was used as a reference. When the ambient temperature was raised to 180° C. at a rate of 0.15° C./min, a diffraction line intensity ratio (the diffraction line intensity after temperature rise/the initial diffraction line intensity×100) at the same peak position was 98%. When the ambient temperature was decreased from 180° C. to 27° C. at a rate of 0.15° C./min, a diffraction line intensity ratio (the diffraction line intensity after temperature decrease/the initial diffraction line intensity×100) at the same peak position was 98%.

As shown in FIG. 6B, in the X-ray diffraction patterns of the pentacene crystals constituting the semiconductor layer of Example 1, the peak of the diffraction line that indicated the maximum peak intensity value was observed at a position of d=1.43 nm. Similarly, as shown in FIG. 6A, in the X-ray diffraction patterns of the energetically most stable bulk crystals of pentacene, the peak of the diffraction line also was observed at a position of d=1.43 nm. Moreover, as shown in FIG. 6B, in the X-ray diffraction patterns of the pentacene crystals constituting the semiconductor layer of Example 1, no diffraction line was observed that was derived from crystal phases other than the crystal phase for which the diffraction line was observed at a position of d=1.43 nm. The total intensity value of diffraction lines derived from the crystal phase for which the diffraction line was observed at a position of d=1.43 nm was 90% or more of the total intensity value of all diffraction lines in the X-ray diffraction patterns of Example 1. The result confirmed that the crystal phase of the pentacene crystals constituting the semiconductor layer of Example 1 was the same as that of the energetically most stable bulk crystals of pentacene.

On the other hand, as shown in FIG. 6C, in the X-ray diffraction patterns of the pentacene crystals constituting the semiconductor layer of Comparative Example 1, the peak of the diffraction line that indicated the maximum peak intensity value was observed at a position of d=1.55 nm. The diffraction line of this peak position was not observed in the X-ray diffraction patterns (FIG. 6A) of the energetically most stable bulk crystals of pentacene. The result confirmed that the crystal phase of the pentacene crystals constituting the semiconductor layer of Comparative Example 1 differed from that of the energetically most stable bulk crystals of pentacene.

As shown in FIG. 6D, in the X-ray diffraction patterns of the pentacene crystals constituting the semiconductor layer of Comparative Example 2, the peak of the diffraction line was observed at two positions d=1.55 nm and d=1.43 nm. The result confirmed that the pentacene crystals constituting the semiconductor layer of Comparative Example 2 included the crystal phase of the energetically most stable bulk crystals of pentacene and the crystal phase of the pentacene crystals constituting the semiconductor layer of Comparative Example 1. The total intensity value of diffraction lines derived from the crystal phase for which the diffraction line was observed at a position of d=1.43 was 45% of the total intensity value of all diffraction lines in the X-ray diffraction patterns of Comparative Example 2.

Change in Crystal Phase Before and after High-Temperature Accelerated Test

Next, a high-temperature accelerated test (60° C.×100 hours) was performed in Example 1, Comparative Example 1, and Comparative Example 2. Further, X-ray diffraction patterns were measured before and after the test, and using the maximum peak intensity value before the test as a reference, a diffraction line intensity ratio (the diffraction line intensity after test/the diffraction line intensity before test×100) at the same peak position was calculated for each of the examples. Moreover, the carrier mobility in the field-effect channel was measured with AGILENT 4155C (4155C manufactured by Agilent Technologies) before and after the test. Table 1 shows the results.

TABLE 1

| | Diffraction line | Carrier mobility (cm²/Vs) | |
|---|---|---|---|
| | intensity ratio | Before test | After test |
| Example 1 | 99% (d = 1.43 nm) | 0.4 | 0.06 |
| Comparative | 60% (d = 1.55 nm) | 0.6 | 0.001 or less |
| Example 1 | | | |
| Comparative | 70% (d = 1.55 nm) | 0.001 or less | 0.001 or less |
| Example 2 | | | |

As shown in Table 1, the diffraction line intensity ratio of Comparative Example 1 was 60%, and the diffraction line intensity at d=1.55 nm was reduced after the test. Although not shown in Table 1, the diffraction line intensity at d=1.43 nm was increased with the above reduction in diffraction line intensity. It is evident from this result that part of the crystal phase before the test was changed to a more stable crystal phase (i.e., a crystal phase of the energetically most stable bulk crystals). Consequently, many grain boundaries were generated between the crystal phases, and the carrier mobility was degraded from 0.6 cm²/Vs to 0.001 cm²/Vs or less. In Comparative Example 2, a plurality of crystal phases were present before the test, and therefore the carrier mobility was 0.001 cm²/Vs or less both before and after the test.

On the other hand, the diffraction line intensity ratio of Example 1 was 99%, and the crystal phase was hardly changed before and after the test. The carrier mobility was degraded from 0.4 cm²/Vs (before the test) to 0.06 cm²/Vs (after the test). However, the degree of degradation of the carrier mobility was suppressed as compared with Comparative Example 1. According to the present invention, a crystal phase of the crystals of the organic semiconductor (pentacene) constituting the semiconductor layer can be the same as a crystal phase of the energetically most stable bulk crystals of the organic semiconductor, thereby suppressing the degradation of carrier mobility over time.

### EXAMPLE 2

Example 2 differs from Example 1 in the organic semiconductor of the semiconductor layer. An organic TFT of Example 2 was produced in the same manner as Example 1 except that the semiconductor layer was formed by depositing copper phthalocyanine (manufactured by Aldrich Chemical Co., Inc.) on the gate insulating layer at a deposition rate of 0.1 nm/min while maintaining the temperature of the substrate at 60° C.

### COMPARATIVE EXAMPLE 3

As a comparative example, an organic TFT of Comparative Example 3 was produced in the same manner as Example 2 except that the semiconductor layer was formed by depositing copper phthalocyanine on the gate insulating layer at a deposition rate of 6 nm/min while maintaining the temperature of the substrate at 30° C.

Change in Crystal Phase Before and after High-Temperature Accelerated Test

Next, a high-temperature accelerated test (60° C.×100 hours) was performed in Example 2 and Comparative Example 3. Like Example 1, the diffraction line intensity ratio and the carrier mobility were measured. Table 2 shows the results.

TABLE 2

| | Diffraction line | Carrier mobility (cm²/Vs) | |
|---|---|---|---|
| | intensity ratio | Before test | After test |
| Example 2 | 99% (d = 1.25 nm) | 0.02 | 0.01 |
| Comparative | 63% (d = 1.30 nm) | 0.01 | 0.001 or less |
| Example 3 | | | |

As shown in Table 2, the diffraction line intensity ratio of Comparative Example 3 was 63%, and the diffraction line intensity at d=1.30 nm was reduced after the test. Although not shown in Table 2, the diffraction line intensity at d=1.25 nm was increased with the above reduction in diffraction line intensity. It is evident from this result that part of the crystal phase before the test was changed to a more stable crystal phase. Consequently, many grain boundaries were generated between the crystal phases, and the carrier mobility was degraded from 0.01 cm²/Vs to 0.001 cm²/Vs or less. On the other hand, the diffraction line intensity ratio of Example 2 was 99%, and the crystal phase was hardly changed before and after the test. Although not shown in the drawings, no diffraction line was observed that was derived from crystal phases other than the crystal phase for which the diffraction line was observed at a position of d=1.25 nm in the X-ray diffraction patterns of Example 2 before the test. The total intensity value of diffraction lines derived from the crystal phase for which the diffraction line was observed at a position of d=1.25 nm was 90% or more of the total intensity value of all diffraction lines in the X-ray diffraction patterns of Example 2. Moreover, the peak position of the diffraction line at d=1.25 nm also was observed in the X-ray diffraction patterns of the energetically most stable bulk crystals of copper phthalocyanine (not shown). The result confirmed that the crystal phase of the copper phthalocyanine crystals constituting the semiconductor layer of Example 2 was the same as that of the energetically most stable bulk crystals of copper phthalocyanine. The carrier mobility was degraded from 0.02 cm²/Vs (before the test) to 0.01 cm²/Vs (after the test). However, the degree of degradation of the carrier mobility was suppressed as compared with Comparative Example 3. Accordingly, like Example 1, Example 2 allows a crystal phase of the crystals of the organic semiconductor (copper phthalocyanine) constituting the semiconductor layer to be the same as a crystal phase of the energetically most stable bulk crystals of the organic semiconductor, thereby suppressing the degradation of carrier mobility over time.

The bulk crystals of copper phthalocyanine were produced by the following method.

Method for Producing the Bulk Crystals of Copper Phthalocyanine

The operation was performed under the same conditions as the method for producing the bulk crystals of pentacene except that copper phthalocyanine powder was put in a silica glass tube, one end of the silica glass tube at which the copper phthalocyanine powder was placed was heated at 320° C., and the pressure inside the silica glass tube was 2.3×10⁻² Pa.

In the X-ray diffraction patterns of the bulk crystals thus produced, the diffraction line intensity at 27° C. for d=1.25 nm was used as a reference. When the ambient temperature was raised to 180° C. at a rate of 0.15° C./min, a diffraction line intensity ratio (the diffraction line intensity after temperature rise/the initial diffraction line intensity×100) at the same peak position was 99%. When the ambient temperature was decreased from 180° C. to 27° C. at a rate of 0.15° C./min, a diffraction line intensity ratio (the diffraction line intensity after temperature decrease/the initial diffraction line intensity×100) at the same peak position was 99%.

### EXAMPLE 3

Example 3 differs from Examples 1 and 2 in the organic semiconductor of the semiconductor layer. An organic TFT of Example 3 was produced in the same manner as Example 1 except that the semiconductor layer was formed by depositing sexithiophene (manufactured by Aldrich Chemical Co., Inc.) on the gate insulating layer at a deposition rate of 0.1 nm/min while maintaining the temperature of the substrate at 60° C.

Change in Crystal Phase Before and after High-Temperature Accelerated Test

Next, a high-temperature accelerated test (60° C.×100 hours) was performed in Example 3. Like Example 1, the diffraction line intensity ratio and the carrier mobility were measured. Table 3 shows the results.

TABLE 3

| | |
|---|---|
| Diffraction line | Carrier mobility (cm²/Vs) |

| | intensity ratio | Before test | After test |
|---|---|---|---|
| Example 3 | 99% (d = 2.24 nm) | 0.02 | 0.01 |

The diffraction line intensity ratio of Example 3 was 99%, and the crystal phase was hardly changed before and after the test. Although not shown in the drawings, no diffraction line was observed that was derived from crystal phases other than the crystal phase for which the diffraction line was observed at a position of d=2.24 nm in the X-ray diffraction patterns of Example 3 before the test. The total intensity value of diffraction lines derived from the crystal phase for which the diffraction line was observed at a position of d=2.24 nm was 90% or more of the total intensity value of all diffraction lines in the X-ray diffraction patterns of Example 3. Moreover, the peak position of the diffraction line at d=2.24 nm also was observed in the X-ray diffraction patterns of the energetically most stable bulk crystals of sexithiophene (not shown). The result confirmed that the crystal phase of the sexithiophene crystals constituting the semiconductor layer of Example 3 was the same as that of the energetically most stable bulk crystals of sexithiophene. The carrier mobility was degraded from 0.02 cm²/Vs (before the test) to 0.01 cm²/Vs (after the test). However, the degree of degradation of the carrier mobility was suppressed. Accordingly, like Examples 1 and 2, Example 3 allows a crystal phase of the crystals of the organic semiconductor (sexithiophene) constituting the semiconductor layer to be the same as a crystal phase of the energetically most stable bulk crystals of the organic semiconductor, thereby suppressing the degradation of carrier mobility over time.

The bulk crystals of sexithiophene were produced by the following method.

Method for Producing the Bulk Crystals of Sexithiophene

The operation was performed under the same conditions as the method for producing the bulk crystals of pentacene except that sexithiophene flake was put in a silica glass tube, one end of the silica glass tube at which the sexithiophene flake was placed was heated at 240° C., and the pressure inside the silica glass tube was 1.6×10⁻² Pa.

In the X-ray diffraction patterns of the bulk crystals thus produced, the diffraction line intensity at 27° C. for d=2.24 nm was used as a reference. When the ambient temperature was raised to 180° C. at a rate of 0.15° C./min, a diffraction line intensity ratio (the diffraction line intensity after temperature rise/the initial diffraction line intensity×100) at the same peak position was 99%. When the ambient temperature was decreased from 180° C. to 27° C. at a rate of 0.15° C./min, a diffraction line intensity ratio (the diffraction line intensity after temperature decrease/the initial diffraction line intensity×100) at the same peak position was 99%.

The examples of the present invention have been described above, but the present invention is not limited thereto. For example, although the X-ray diffraction was used to confirm the crystal phase in the examples, other analytical methods such as absorptiometric analysis may be used instead. In the above examples, the organic TFT with a so-called bottom gate structure in which the gate electrode is formed on the substrate was described. However, it is also possible to use an organic TFT with a so-called top gate structure in which the source electrode and the drain electrode are formed on the substrate, and the semiconductor layer, the gate insulating layer, and the gate electrode are formed successively thereon.

### INDUSTRIAL APPLICABILITY

As described above, the present invention can suppress the degradation of carrier mobility of an organic TFT over time, and thus can be used suitably for electronic equipment that requires a longer life.

1. An organic thin film transistor comprising:
a substrate; and
a semiconductor layer made of an organic semiconductor and formed on the substrate,
wherein the semiconductor layer is composed of crystals of the organic semiconductor, and
a crystal phase of the crystals is the same as a crystal phase of energetically most stable bulk crystals of the organic semiconductor.

2. The organic thin film transistor according to claim 1, wherein a peak position of a diffraction line that indicates a maximum peak intensity value in X-ray diffraction patterns of the crystals constituting the semiconductor layer coincides with a peak position of any one of diffraction lines in X-ray diffraction patterns of the energetically most stable bulk crystals of the organic semiconductor.

3. The organic thin film transistor according to claim 2, wherein a total intensity value of diffraction lines derived from a crystal phase having the maximum peak intensity value is 90 to 100% of a total intensity value of all diffraction lines in the X-ray diffraction patterns of the crystals constituting the semiconductor layer.

4. The organic thin film transistor according to claim 1, wherein the organic semiconductor includes at least one material selected from an acene-based material, a phthalocyanine-based material, and a thiophene-based material.

5. The organic thin film transistor according to claim 2, wherein the organic semiconductor is pentacene, and
the peak of the diffraction line that indicates the maximum peak intensity value in the X-ray diffraction patterns of the crystals constituting the semiconductor layer is positioned at d=1.43 nm, where d represents a distance between the Bragg planes of the crystals.

6. The organic thin film transistor according to claim 2, wherein the organic semiconductor is copper phthalocyanine, and
the peak of the diffraction line that indicates the maximum peak intensity value in the X-ray diffraction patterns of the crystals constituting the semiconductor layer is positioned at d=1.25 nm, where d represents a distance between the Bragg planes of the crystals.

7. The organic thin film transistor according to claim 2, wherein the organic semiconductor is sexithiophene, and
the peak of the diffraction line that indicates the maximum peak intensity value in the X-ray diffraction patterns of the crystals constituting the semiconductor layer is positioned at d=2.24 nm, where d represents a distance between the Bragg planes of the crystals.

8. The organic thin film transistor according to claim 1, wherein the substrate is a plastic plate.

9. The organic thin film transistor according to claim 8, wherein the plastic plate is made of any one of materials selected from polyimide, aromatic polyester, polyacetal, polyurea, and polyphenyl sulfone.

10. The organic thin film transistor according to claim 1, wherein the substrate is a plastic film.

11. The organic thin film transistor according to claim 10, wherein the plastic film is made of any one of materials selected from polyimide, aromatic polyester, polyacetal, polyurea, and polyphenyl sulfone.

12. The organic thin film transistor according to claim 1, further comprising electrodes for transferring charge to the semiconductor layer,
wherein the electrodes are made of at least one selected from a metal and a conductive polymer.

13. The organic thin film transistor according to claim 12, wherein the electrodes include at least one material selected from gold, copper, nickel, aluminum, titanium, molybdenum, polypyrrole, polythiophene, polyaniline, and polyphenylene vinylene.

14. A method for manufacturing an organic thin film transistor comprising:
forming a semiconductor layer by depositing an organic semiconductor on a substrate,
wherein the organic semiconductor is deposited at a deposition rate of 0.1 to 1 nm/min while maintaining a temperature of the substrate in a range of 40 to 150° C.

15. The method according to claim 14, further comprising:
cooling the semiconductor layer slowly after the semiconductor layer is formed by depositing the organic semiconductor.

16. The method according to claim 15, wherein the semiconductor layer is cooled slowly by decreasing an ambient temperature around the semiconductor layer at a rate of 1° C./min or less.

17. The method according to claim 14, further comprising:
heat-treating the semiconductor layer while maintaining the temperature of the substrate in a range of 50 to 150° C. after the semiconductor layer is formed by depositing the organic semiconductor.

18. The method according to claim 14, further comprising:
forming an electrode by depositing an electrode material on the semiconductor layer while maintaining the temperature of the substrate at 45° C. or less after the semiconductor layer is formed by depositing the organic semiconductor.

19. An active matrix display comprising:
a plurality of the organic thin film transistors according to claim 1 as switching elements for pixels.

20. A radio recognition tag comprising:
an integrated circuit portion,
wherein the integrated circuit portion comprises the organic thin film transistor according to claim 1.
